(19) United States
(12) Patent Application Publication
(10) Pub. No.: US 2007/0235759 A1
(43) Pub. Date: Oct. 11, 2007

(54) CMOS process with Si gates for nFETs and SiGe gates for pFETs

(75) Inventors: William K. Henson, Peekskill, NY (US); Yaocheng Liu, Elmsford, NY (US); Alexander Reznicek, Mount Kisco, NY (US); Kern Rim, Yorktown Heights, NY (US); Devendra K. Sadana, Pleasantville, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: International Business Machines Corporation, Armonk, NY (US)

(21) Appl. No.: 11/401,672

(22) Filed: Apr. 11, 2006

(51) Int. Cl. H01L 31/00

(52) U.S. Cl. 257/192

(57) ABSTRACT

An integration scheme for providing Si gates for nFET devices and SiGe gates for pFET devices on the same semiconductor substrate is provided. The integration scheme includes first providing a material stack comprising, from bottom to top, a gate dielectric, a Si film, and a hard mask on a surface of a semiconductor substrate that includes at least one nFET device region and at least one pFET device region. Next, the hard mask is selectively removed from the material stack in the at least one pFET device region thereby exposing the Si film. The exposed Si film is then converted into a SiGe film and thereafter at least one nFET device is formed in the least one nFET device region and at least one pFET device is formed in the at least one pFET device region. In accordance with the present invention, the least one nFET device includes a Si gate and the at least one pFET includes a SiGe gate.

### FIELD OF THE INVENTION

The present invention relates to a semiconductor structure and a method of fabricating the same. More particularly, the present invention relates to a semiconductor structure including Si gates for nFET devices and SiGe gates for pFET devices and a method of fabricating such a structure.

### BACKGROUND OF THE INVENTION

Performance gains in high performance logic circuits rely on increasing the ‘on’ current without increasing the ‘off’ current. As device dimensions are scaled, performance gains are more difficult to achieve. One particular aspect of scaling involves reducing the physical thickness of the gate oxide. For a given gate voltage, an electric field is established across the gate oxide. If the gate oxide is reduced, then the magnitude of the electric field increases for the same gate voltage. In the case of a pFET device, a negative voltage is applied to the gate to turn ‘on’ the device. When the device is in the ‘on’ state, the channel becomes inverted with respect to its majority carrier type. As inversion charges in the channel increase, the gate becomes depleted of its majority carrier.

Depletion of charge carriers at, or near, the interface between the gate oxide/poly-Si gate (known as the poly depletion effect) has been a problem for complementary metal oxide semiconductor (CMOS) devices, and in particular for pFET devices. The depletion causes a virtual increase in gate dielectric thickness thereby adversely impacting device performance. The effect of the depletion becomes increasingly important with progressively decreasing gate oxide thickness because the poly depletion effect increase becomes fractionally higher.

For 65 nm and beyond CMOS technologies, the depletion accounts for a significant fraction of the total gate dielectric related capacitance. Poly depletion in pFETs is attributed mainly to incomplete activation of boron at the gate oxide/poly-Si interface due to the low boron activation level in poly-Si.

To minimize this depletion, poly-SiGe is being considered as an alternative gate material because it allows much higher electrical activation of boron at low annealing temperatures. The lowering of activation temperature scales with Ge concentration in the SiGe gate. For example, the higher the Ge content, the lower the activation temperature. However, for nFETs, a poly-Si gate is a better choice than poly-SiGe because n-type dopant activation in poly-SiGe is lower than that in poly-Si. Therefore, the use of poly-SiGe gates for pFETs, and poly-Si gates for nFETs is expected to provide optimum performance.

Despite the above, there is no known simple approach to provide a semiconductor structure in which poly-Si gates for nFET devices are integrated with poly-SiGe gates for pFET devices.

### SUMMARY OF THE INVENTION

The present application provides a simple approach to integrate nFETs with Si gates and pFETs with SiGe gates in complementary metal oxide semiconductor (CMOS) circuits. Because of the higher boron (or other p-type dopant) activation in SiGe, pFET device performance can be improved due to much reduced poly depletion. The inventive approach has no significant impact on nFET device performance. Therefore, the inventive method provides a new performance gain by using SiGe gates on pFET devices. The inventive integration scheme is quite manufacturable, with little or no cost impact.

In general terms, the method of the present invention includes the steps of:

providing a material stack comprising, from bottom to top, a gate dielectric, a Si film, and a hard mask on a surface of a semiconductor substrate, said substrate including at least one nFET device region and at least one pFET device region;

selectively removing said hard mask from said material stack in said at least one pFET device region thereby exposing said Si film;

converting said Si film that is exposed in said at least one pFET device region into a SiGe film; and

forming at least one nFET device in said at least one nFET device region and at least one pFET device in said at least one pFET device region, said at least one nFET device including a Si gate and said at least one pFET including a SiGe gate.

The present invention provides three embodiments to the general method described above. In accordance with the first embodiment of the general method, after formation of a gate dielectric on a surface of a semiconductor substrate, a thin film of poly-Si or amorphous Si (on the order of about 10 nm or less) is deposited on the gate dielectric. Next, a hard mask such as SiO₂ is formed atop the thin film of poly-Si or amorphous Si (herein after this thin film is referred to as a Si film). The hard mask is then patterned (by lithography and etching) to expose the Si film in the areas in which pFET devices are to be formed. After stripping the resist used in patterning the hard mask, the structure is heated in a chamber with a Ge-containing gas at high temperatures (on the order of about 200° C. or greater) so that Ge atoms, which are generated by decomposition of the Ge-containing gas, diffuse into the exposed Si film and form a SiGe film. During the heating step, the remaining hard mask atop the nFET device region acts to block that region from receiving Ge atoms. After the heating step, an etching process can be used in removing the remaining hard mask from the structure and further Si deposition to achieve a targeted thickness value can be performed. After the final Si film deposition, a traditional CMOS process flow can be performed to form at least one Si-gated device in the nFET device region, and at least one SiGe-gated device in the pFET device region.

The second embodiment of the inventive method is similar to the first embodiment described above except that instead of heating the structure in a chamber with a Ge-containing gas the annealing occurs ex-situ. In this embodiment of the present invention, a Ge-containing layer (pure Ge or a SiGe alloy) is deposited selectively atop the exposed Si film. Next, an annealing process is performed which is capable of diffusing Ge atoms into the Si film so as to form a SiGe film.

The third embodiment of the present invention is similar to the first and second embodiments but that a thicker Si film can be used as the initial film within the material stack. After forming a Ge-containing film atop the Si film, the resultant structure is subjected to a thermal oxidation process (a ‘Ge condensation’ process) in which Ge is segregated out from the newly produce oxide film and interdiffuses between the Ge-containing film and the Si film forming a new SiGe film. As a result of the oxidation, the Ge-containing film is condensed, i.e., the Ge concentration is increased. As the same time, the thicknesses of both the Ge-containing and Si films are adjusted. Next, the oxide layer formed during thermal oxidation is removed and another Si film can be formed to reach a final gate thickness.

In addition to the integration scheme and various embodiments mentioned above, the present invention also relates to a semiconductor structure that is formed thereby. Specifically, the invention semiconductor structure comprises:

a first gate stack located within an nFET device region of a semiconductor substrate, said first gate stack comprising, from bottom to top, a gate dielectric, a first Si layer, and a second Si layer; and

a second gate stack located within a pFET device region of said semiconductor substrate, said second gate stack comprising, from bottom to top, the gate dielectric, a SiGe layer, and a Si layer.

### BRIEF DESCRIPTION OF THE DRAWINGS

FIGS. 1A-1G are pictorial representations (through cross sectional views) depicting a first embodiment of the present invention.

FIGS. 2A-2D are pictorial representations (through cross sectional views) depicting a second embodiment of the present invention.

### DETAILED DESCRIPTION OF THE INVENTION

The present invention, which provides a CMOS process with Si gates for nFET devices and SiGe gates for pFET devices, will now be described in greater detail by referring to the following discussion and drawings that accompany the present application. The drawings of the present application, which are referred to herein below in greater detail, are provided for illustrative purposes and, as such, they are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

The present invention provides a CMOS process for producing a semiconductor structure including nFET devices including Si gates and pFET devices including SiGe gates. The method of the present invention provides a simple approach for fabricating such a semiconductor structure. In general terms, the inventive method includes first providing a material stack comprising, from bottom to top, a gate dielectric, a Si film, and a hard mask on a surface of a semiconductor substrate that includes at least one nFET device region and at least one pFET device region. Next, the hard mask is selectively removed from the material stack in the at least one pFET device region thereby exposing the Si film. The exposed Si film is converted into a SiGe film and thereafter at least one nFET device is formed in the least one nFET device region and at least one pFET device is formed in the at least one pFET device region. In accordance with the present invention, the at least one nFET device includes a Si gate and the at least one pFET includes a SiGe gate. In a preferred embodiment, the nFET device includes a poly-Si gate, while the pFET device includes a poly-SiGe gate.

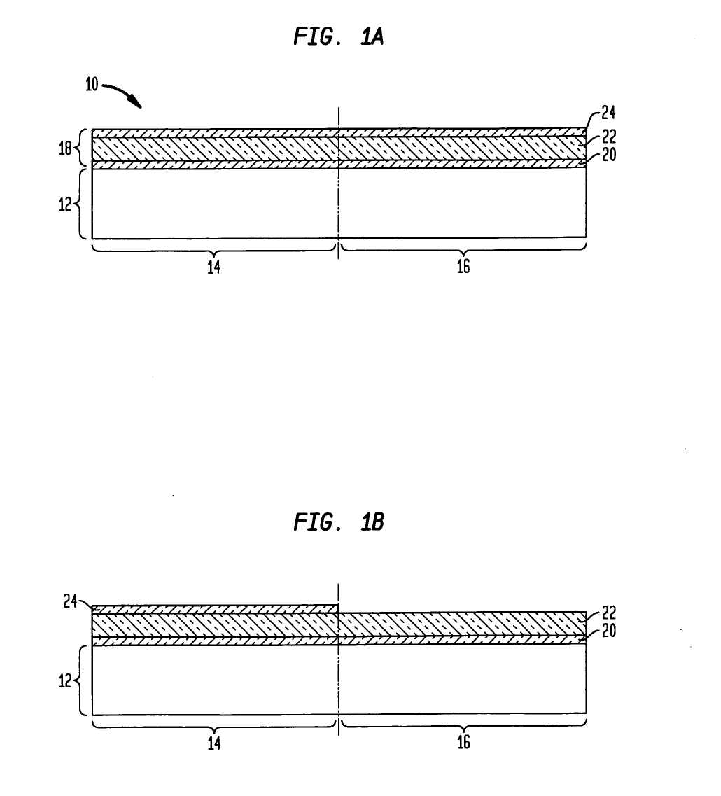

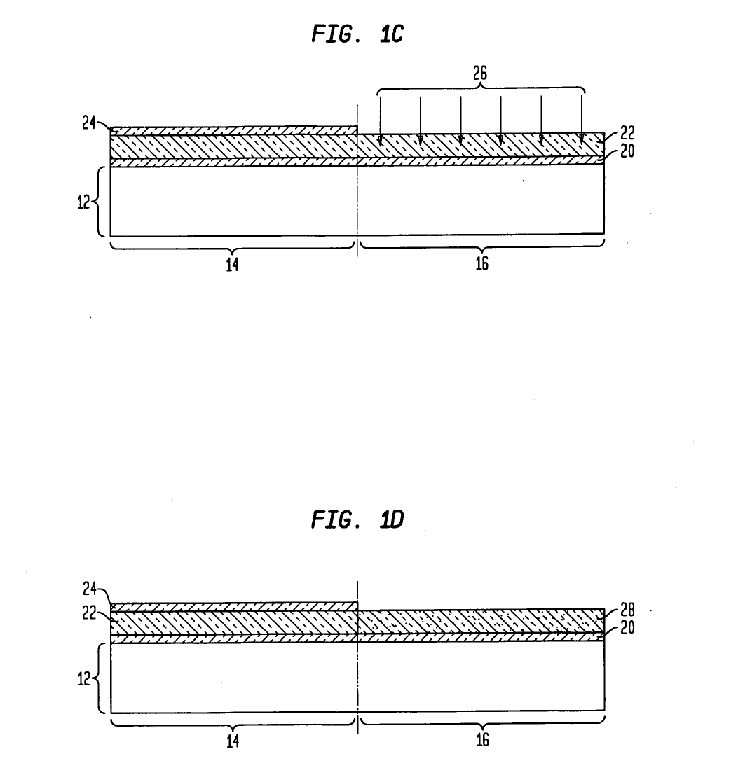

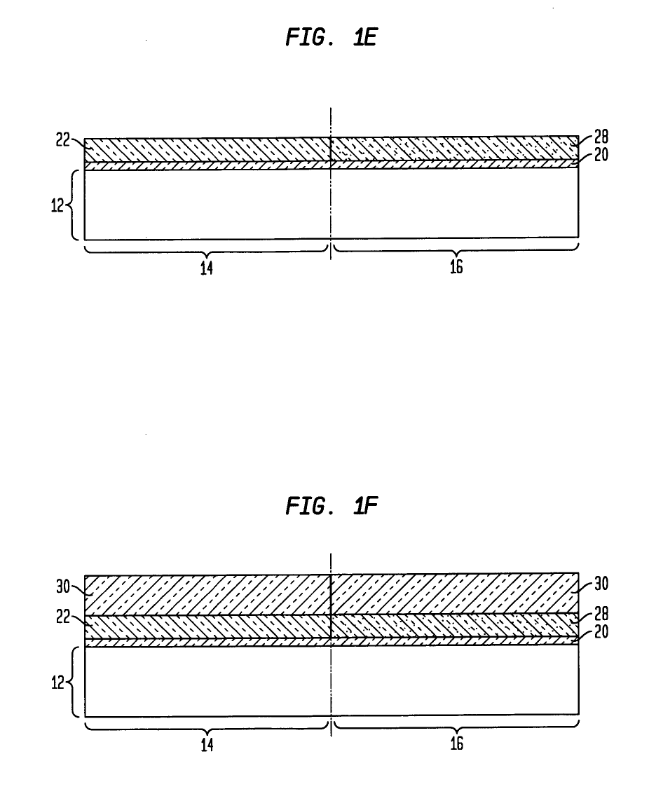

Reference is first made to FIGS. 1A-1G which illustrates a first embodiment of the present invention. In the first embodiment of the present invention, the SiGe gate of the pFET device is formed by introducing Ge atoms from a Ge-containing source gas into a Si film, while the Si film in areas in which nFET devices are to be fabricated is protected by an overlying hard mask. Reference is first made to FIG. 1A which illustrates an initial structure 10 that is employed in the first embodiment of the present invention. As is illustrated, the initial structure 10 includes a semiconductor substrate 12 that includes at least one nFET device region 14 and at least one pFET device region 16. The initial structure 10 also includes a material stack 18 located atop the substrate 12 in both the nFET device region 14 and the pFET device region 16. The material stack 18 includes, from bottom to top, a gate dielectric 20, a Si film 22 and a hard mask 24.

The semiconductor substrate 12 of the initial structure 10 includes any semiconducting material including, for example, Si, SiGe, SiGeC, SiC, Ge alloys, GaAs, InAs, InP and other III/V or II/VI compound semiconductors. In addition to these listed types of semiconducting materials, the present invention also contemplates cases in which the semiconductor substrate 12 is a layered semiconductor such as, for example, Si/SiGe, Si/SiC, silicon-on-insulators (SOIs) or silicon germanium-on-insulators (SGOIs). In some embodiments of the present invention, it is preferred that the semiconductor substrate 12 be composed of a Si-containing semiconductor material, i.e., a semiconductor material that includes silicon. The semiconductor substrate 12 may be doped, undoped or contain doped and undoped regions therein.

It is also noted that the semiconductor substrate 12 may be strained, unstrained or contain strained regions and unstrained regions therein. The semiconductor substrate 12 may also have a single crystal orientation or alternatively, the substrate 12 may be a hybrid semiconductor substrate that has surface regions having different crystallographic orientations. For example, the semiconductor substrate 12 within the nFET device region 14 may have a surface crystal orientation that is (100), while the semiconductor substrate within the pFET device region 16 may have a surface crystal orientation that is (110). The hybrid substrates may have bulk characteristics, SOI like characteristics or combinations of both bulk and SOI characteristics.

The semiconductor substrate 12 may also have one or more isolation regions (not shown) such as, for example, trench isolation regions or field oxide isolation regions, located therein. The one or more isolation regions, which are typically present between the nFET device region and pFET device region, are formed utilizing conventional processing which is well known to those skilled in the art of semiconductor device manufacturing.

The gate dielectric 20 of the material stack 18 is formed on the surface of the semiconductor substrate 12 after the substrate has been processed. The gate dielectric 20 can be formed by a thermal growing process such as, for example, oxidation. Alternatively, the gate dielectric 20 can be formed by a deposition process such as, for example, chemical vapor deposition (CVD), plasma-assisted CVD, atomic layer or pulsed deposition (ALD or ALPD), evaporation, reactive sputtering, chemical solution deposition or other like deposition processes. The gate dielectric 20 may also be formed utilizing any combination of the above processes.

The gate dielectric 20 is comprised of an insulating material (or material stack) having a dielectric constant of about 4.0 or greater, preferably greater than 7.0. The dielectric constants mentioned herein are relative to a vacuum, unless otherwise stated. Note that SiO₂ typically has a dielectric constant that is about 4.0. Specifically, the gate dielectric 20 employed in the present invention includes, but is not limited to: an oxide, nitride, oxynitride and/or silicates including metal silicates, aluminates, titanates and nitrides. In one embodiment, it is preferred that the gate dielectric 20 is comprised of an oxide such as, for example, SiO₂, HfO₂, ZrO₂, Al₂O₃, TiO₂, La₂O₃, SrTiO₃, LaAlO₃, Y₂O₃ and mixtures thereof. Of these oxides, SiO₂ is typically used as the gate dielectric material.

The physical thickness of the gate dielectric 20 may vary, but typically, the gate dielectric 20 has a thickness from about 0.5 to about 10 nm, with a thickness from about 0.5 to about 5 nm being more typical.

After forming the gate dielectric 20, a Si film 22 is formed on the gate dielectric 20 utilizing a known deposition process such as, for example, physical vapor deposition (PVP), CVD or evaporation. The Si film 22 may be polycrystalline or amorphous, with polycrystalline being highly preferred in the present application. The Si film 22 is typically undoped at this point of the present invention. Typically, the Si film 22 used in this embodiment of the present invention is a thin film having a vertical thickness that is 10 nm or less, with a thickness from about 2 to about 5 nm being more typical.

The material stack 18 shown in FIG. 1A also includes a hard mask 24 which is formed atop the Si film 22. The hard mask 24 can be formed utilizing a thermal process such as, for example, oxidation, nitridation or oxynitridation. Alternatively, a deposition process such as, for example, CVD, PECVD, PVD, atomic layer deposition, evaporation or chemical solution deposition, can be used in forming the hard mask 24. Combinations of the aforementioned techniques are also contemplated for forming the hard mask 24. The hard mask 24 is comprised of an oxide, nitride, oxynitride, or any combination, including multilayers thereof. Typically, the hard mask 24 is comprised of SiO₂.

The thickness of the hard mask 24 may vary depending on, for example, the technique used in forming that material layer as well as the number of layers within the hard mask 24. Typically, the hard mask 24 of the material stack 18 has a thickness from about 2 to about 100 nm, with a thickness from about 5 to about 50 nm being even more typical.

After forming the hard mask 24 of the material stack 18, a blanket layer of photoresist material (not shown) is then formed atop the hard mask 24. The photoresist material employed in the present invention includes a conventional positive-tone, negative-tone or hybrid photoresist. The photoresist material is formed by a conventional deposition process including, for example, spin-on coating, CVD, PECVD, or evaporation. After forming the blanket layer of photoresist material on the hard mask 24, the photoresist material is subjected to lithography which includes exposing the resist to a desired pattern of radiation and developing the exposed resist material utilizing a conventional resist developer. In the present application, the lithographic process provides a patterned photoresist material that is present atop the hard mask 24 in the nFET device region 14, while the hard mask 24 in the pFET device region 16 is unprotected.

The unprotected hard mask 24 within the pFET device region 16 is then selectively removed utilizing an etching process that is capable of selectively removing the exposed hard mask 24, stopping on a surface of the underlying Si film 22. The resultant structure that is formed after the selective removal process has been performed is shown, for example, in FIG. 1B. The etching process performed in forming the structure shown in FIG. 1B includes dry etching such as, for example, reactive ion etching, ion beam etching or plasma etching, or a chemical wet etching process. When a chemical wet etching process is used in selectively removing the exposed hard mask 24 from the pFET device region 16, a chemical etchant such as, for example, HF, can be used to remove the exposed portion of the hard mask 24. As shown, the underlying Si film 22 within the pFET device region 16 is exposed after the selective removal process has been performed. After etching, the patterned photoresist material is stripped from the structure utilizing a conventional resist stripping process.

At this point of the first embodiment of the present invention, Ge atoms 26 are introduced into the exposed portion of the Si film such as is shown in FIG. 1C. The Ge atoms 26 are introduced by first providing a Ge-containing source gas into a reactor chamber including the structure shown in FIG. 1B and then heating the Ge-containing source gas at a temperature that is sufficient to cause decomposition of the Ge-containing source gas into at least Ge atoms. The Ge-containing source gas used in the present invention includes a GeₐX_{b} compound wherein each X is the same or different and is H (Hydrogen), Cl (Chlorine) or metallorganic compounds, a is 1 or 2, and b is 2, 4 or 6. Preferably, the Ge-containing source gas is GeH₄.

After providing the Ge-containing source gas into the reactor chamber, the Ge-containing source gas is heated to a temperature of about 200° C. or greater, with a temperature from about 350° to about 800° C. being even more typical. The temperature used in the present invention is sufficient enough to cause decomposition of the Ge-containing source gas into at least a gas include Ge atoms. An inert carrier gas such as, for example, Ar or He, can be present. It is noted that at the above temperatures, the Ge atoms that are formed are introduced into the Si film 22 by diffusion. The amount of Ge atoms that diffuse into the Si film may vary depending on the initial content of Ge atoms that is generated from the Ge-containing source gas. Typically, this step of the present invention provides a concentration of about greater than 5E20 Ge atoms/cm³ into the exposed portion of the Si film 22. Because of the remaining hard mask 24 that is present atop the nFET device region 14, Ge is not introduced in the Si film 22 in that area of the structure.

FIG. 1D illustrates the structure that is formed after the Ge atoms 26 are introduced into the Si film forming SiGe film 28 in the pFET device region 16. As shown, the nFET device region 14 includes a Si film 22, whereas the pFET device region 16 includes a SiGe film 28.

FIG. 1E shows the structure that is formed after the remaining hard mask 24 has been removed from atop the Si film 22. The remaining hard mask 24 is removed utilizing one of the etching processes described above in removing the hard mask 24 from atop the pFET device region 16.

FIG. 1F shows the structure after an additional Si film 30 has been blanket deposited atop the Si film 22 and the SiGe film 28 in both the nFET device region 14 and the pFET device region 16, respectively. The step is optional and need not be performed in each instance. The additional Si film 30 is formed utilizing one of the deposition process described above in connection with forming the Si film 22. The Si film 30 may be poly-Si or amorphous Si. The thickness of the additional Si film 30 added at this point of the present invention is typically from about 20 to about 100 nm. This step of the present invention adjusts the height of each of the gate regions to a targeted value; the height of each of the gate regions is substantially the same within each of the device regions.

FIG. 1G shows the structure that is formed after further CMOS processing wherein one nFET device 32 is formed within the nFET device region 14 and at least one pFET device 34 is formed within the pFET device region 16. The at least one nFET device 32 includes a patterned gate stack comprising, from bottom to top, the gate dielectric 20, the Si film 22, and the additional Si film 30. The at least one pFET device 34 includes a patterned gate stack comprising, from bottom to top, the gate dielectric 20, the SiGe film 28, and the additional Si film 30.

The patterned gate stacks shown in FIG. 1G are formed by lithography and etching. The lithographic process includes applying a photoresist material (not shown) to the additional Si film 30, exposing the photoresist material to a pattern of radiation, and developing the exposed resist utilizing a conventional resist developer. Etching of the patterned stacks is typically performed utilizing a dry etching process such as reactive ion etching, ion beam etching, or plasma etching. Alternatively, a chemical wet etching process can be used to etch each of the gate stacks. In addition to these specified etching techniques, the present invention also contemplates utilizing any combination thereof.

In some embodiments of the present invention, a dielectric cap layer (not shown) such as an oxide, nitride, oxynitride or multilayer thereof, is formed atop the additional Si film 30 prior to patterning. In yet another embodiment of the present invention, ion implantation and annealing can occur prior to or after a subsequent etching step that patterns the gate stacks. The ions are typically implanted into the Si film 22 and/or the SiGe film 28. The doping of the Si film 22 or SiGe 28 will shift the workfunction of the electrode formed.

Each FET may also include at least one spacer 36 that is typically, but not always, formed on exposed sidewalls of each patterned gate stack. The at least one spacer 36 is comprised of an insulator such as an oxide, nitride, oxynitride and/or any combination thereof. The at least one spacer 36 is formed by deposition and etching. The width of the at least one spacer 36 must be sufficiently wide such that the source and drain silicide contacts (to be subsequently formed) do not encroach underneath the edges of the patterned gate stack. Typically, the source/drain silicide does not encroach underneath the edges of the patterned gate stack when the at least one spacer 36 has a width, as measured at the bottom, from about 20 to about 80 nm.

The patterned gate stacks can also be passivated at this point of the present invention by subjecting the same to a thermal oxidation, nitridation or oxynitridation process. The passivation step forms a thin layer of passivating material (not shown) about the material stack. This step may be used instead or in conjunction with the previous step of spacer formation. When used with the spacer formation step, spacer formation occurs after the material stack passivation process.

Source/drain diffusion regions 38 are then formed into the substrate 12 at this point of the present invention. The source/drain diffusion regions 38 are formed utilizing ion implantation and an annealing step. A raised source/drain process may be used. The annealing step serves to activate the dopants that were implanted by the previous implant step. The conditions for the ion implantation and annealing are well known to those skilled in the art. The source/drain diffusion regions 38 may also include extension implant regions which are formed prior to source/drain implantation using a conventional extension implant. The extension implant may be followed by an activation anneal, or alternatively the dopants implanted during the extension implant and the source/drain implant can be activated using the same activation anneal cycle. Halo implants are also contemplated herein.

Further CMOS processing such as formation of silicided contacts (source/drain and gate) as well as formation of BEOL (back-end-of-the-line) interconnect levels with metal interconnects can be formed utilizing processing steps that are well known to those skilled in the art.

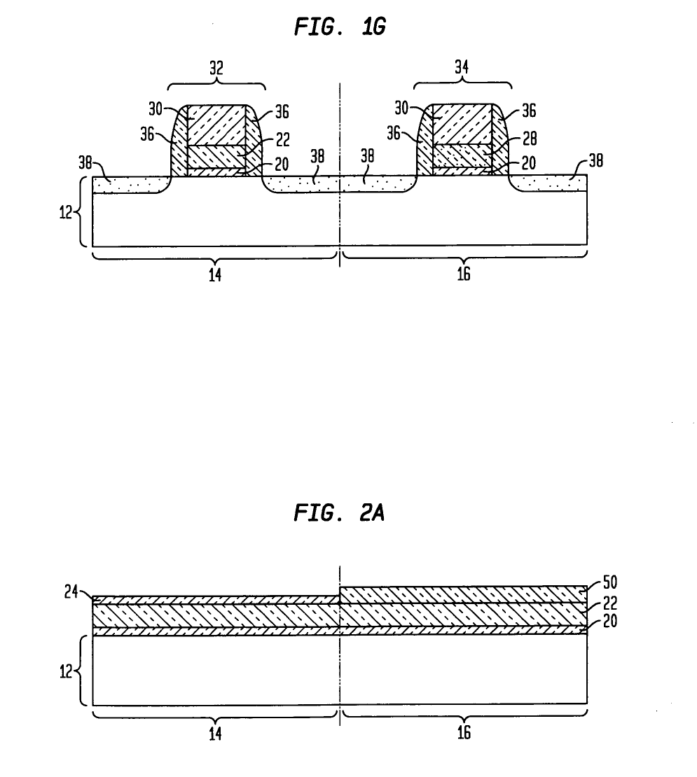

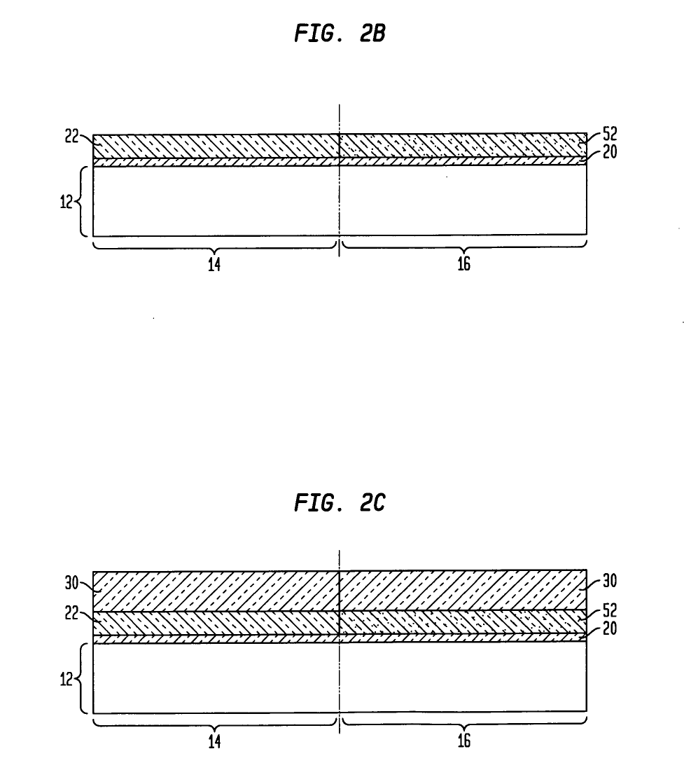

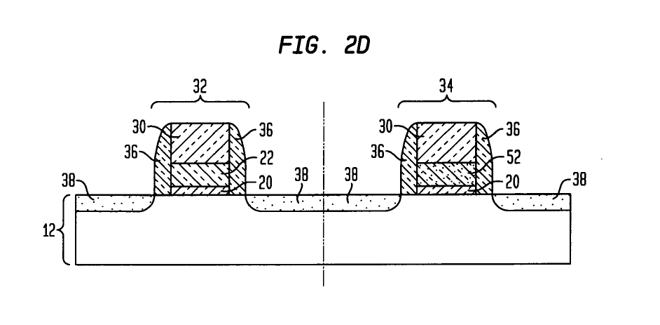

Reference is now made to FIGS. 2A-2D which illustrate a second embodiment of the present invention. The second embodiment of the inventive method is similar to the first embodiment described above except that instead of heating the structure in a chamber with a Ge-containing gas, a Ge-containing layer (pure Ge or a SiGe alloy) is deposited selectively atop the exposed Si film and an annealing process is then performed ex-situ which is capable of diffusing Ge atoms into the Si film so as to form a SiGe film.

Specifically, in the second embodiment of the present invention, the structure shown in FIG. 1B is first provided utilizing the various processing steps described above in the first embodiment. At this point of the second embodiment, a Ge-containing layer 50 is formed atop the surface of the exposed Si film 22 in the pFET device region 16. The resultant structure in the Ge-containing layer 50 is shown, for example, in FIG. 2A.

The Ge-containing layer 50 includes a SiGe alloy or pure Ge. The term “SiGe alloy” includes SiGe materials that comprise up to 99.99 atomic percent Ge, whereas pure Ge includes layers that comprise 100 atomic percent Ge. When SiGe layers are employed, it is preferred that the Ge content in the SiGe layer be from about 0.1 to about 99.9 atomic percent, with a Ge atomic percent of from about 10 to about 35 being even more highly preferred. The SiGe alloys may be single-crystal, amorphous or polycrystalline.

In accordance with the present invention, the Ge-containing layer 50 is formed atop the exposed Si film 22 using any conventional epitaxial growth method that is well known to those skilled in the art. Illustrative examples of epitaxial growing processes that can be used in the present invention include, but are not limited to: low-pressure chemical vapor deposition (LPCVD), ultra-high vacuum chemical vapor deposition (UHVCVD), atmospheric pressure chemical vapor deposition (APCVD), molecular beam (MBE) epitaxy and plasma-enhanced chemical vapor deposition (PECVD).

The thickness of the Ge-containing layer 50 formed at this point of the present invention may vary, but typically the Ge-containing layer 50 has a thickness from about 10 to about 500 nm, with a thickness from about 20 to about 200 nm being more highly preferred.

After forming the Ge-containing layer 50 atop the exposed Si film 22 in the pFET device region 16, the structure shown, for example, in FIG. 2A is then heated, i.e., annealed, at a temperature which causes diffusion of Ge atoms into layers 22 in the pFET device region 16 thereby forming a SiGe layer 52 atop the gate dielectric 20 in the pFET device region 16. Following the heating step, an etching process is used that is capable of removing the remaining hard mask 24 from atop the nFET region 14. The resultant structure formed after the heating step and etching of the remaining hard mask 24 is shown, for example in FIG. 2B.

The heating step that causes the diffusion of Ge atoms from the Ge-containing layer 50 into the exposed Si film 22 is performed in an inert ambient such as, for example, He, Ar, Ne, N₂ or mixtures thereof is preferred at a temperature of about 200° C. or greater.

FIG. 2C shows the structure after an additional Si film 30 has been blanket deposited atop both the Si film 22 and the SiGe layer 52 in both the nFET device region 14 and the pFET device region 16, respectively. The step is optional and need not be performed in each instance. The additional Si film 30 is formed utilizing one of the deposition processes described above in connection with forming the Si film 22. The Si film 30 may be poly-Si or amorphous Si. The thickness of the additional Si film added at this point of the present invention is typically from about 20 to about 100 nm. This step of the present invention adjust the height of each of the gate regions to a targeted value.

FIG. 2D shows the structure that is formed after further CMOS processing wherein at least one nFET device 32 is formed within the nFET device region 14 and at least one pFET device 34 is formed within the pFET device region 16. The at least one nFET device 32 includes a patterned stack comprising, from bottom to top, the gate dielectric 20, the Si film 22, and the additional Si film 30. The at least one pFET device 34 includes a patterned stack comprising, from bottom to top, the gate dielectric 20, the SiGe layer 52, and the additional Si film 30. Each FET also includes a spacer 36 and a source/drain region 38 as described above.

Further CMOS processing such as formation of silicided contacts (source/drain and gate) as well as formation of BEOL (back-end-of-the-line) interconnect levels with metal interconnects can be formed utilizing processing steps that are well known to those skilled in the art.

The third embodiment of the present invention is similar to the first and second embodiments but that a thicker Si film 22 (on the order of about 5 nm or greater) can be used as the initial film within the material stack. After forming a Ge-containing film utilizing the different techniques mentioned in the first and second embodiments, the resultant structure is subjected to a thermal oxidation process (a ‘Ge condensation’ process) in which Ge is segregated out from the newly produce oxide film and interdiffuses between the Ge-containing film and the Si film forming a new SiGe film. As a result of the oxidation, the Ge-containing film is condensed, i.e., the Ge concentration is increased. At the same time, the thicknesses of both the Ge-containing and Si films are adjusted. Next, the oxide layer formed during thermal oxidation is removed and another Si film 30 can be formed to reach a final gate thickness.

Note that an oxide layer (not shown) is typically formed atop the SiGe layer 52 during the thermal oxidation process of the third embodiment of the present invention. The surface oxide layer is typically, but not always, removed from the structure after the heating step using a conventional wet etch process wherein a chemical etchant such as HF that has a high selectivity for removing oxide as compared to SiGe is employed. During this etching step, and in instances wherein the remaining hard mask 24 atop the nFET region 14 is an oxide, the remaining oxide hard mask 24 can be removed.

The surface oxide layer formed after the thermal oxidation step of the present invention has a variable thickness which may range from about 10 to about 1000 nm, with a thickness of from about 20 to about 500 nm being more highly preferred.

The heating temperature used to ‘thermally mix’ layers 50 and 22 which is a function of Ge content in the Ge-containing layer 50, may be from about 200° C. to about 1300° C.

Moreover, the thermal oxidation step of the third embodiment of the present invention which achieves ‘Ge condensation’ is carried out in an oxidizing ambient which includes at least one oxygen-containing gas such as O₂, NO, N₂O, ozone, air and other like oxygen-containing gases. The oxygen-containing gas may be admixed with each other (such as an admixture of O₂ and NO), or the gas may be diluted with an inert gas such as He, Ar, N₂, Xe, Kr, or Ne. Generally, a nitride hard mask 24 is preferred to block the nFET region 14 from being oxidized.

The thermal oxidation step may be carried out for a variable period of time which typically ranges from about 1 sec to about 1800 minutes, with a time period of from about 1 minutes to about 600 minutes being more highly preferred. The thermal oxidation step may be carried out at a single targeted temperature, or various ramp and soak cycles using various ramp rates and soak times can be employed. A soak step may be used below the actual melting point of a given SiGe alloy to tailor the types of defects present in the structure.

The thermal oxidation step is performed under an oxidizing ambient to achieve the presence of a surface oxide layer, which acts as a diffusion barrier to Ge atoms. Therefore, once the oxide layer is formed on the surface of the structure, Ge becomes trapped between the gate dielectric 20 and the surface oxide layer. As the surface oxide increases in thickness, the Ge becomes more uniformly distributed throughout the Si film and the Ge-containing layer, but it is continually and efficiently rejected from the encroaching oxide layer. So as the (now homogenized) layers are thinned during this heating step, the relative Ge fraction increases.

Following the ‘Ge condensation’ process described above and if not previously been done, the remaining hard mask 24 is stripped from the nFET device region 14 utilizing the techniques described above.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of forming a semiconductor structure comprising:
providing a material stack comprising, from bottom to top, a gate dielectric, a Si film, and a hard mask on a surface of a semiconductor substrate, said substrate including at least one nFET device region and at least one pFET device region;
selectively removing said hard mask from said material stack in said at least one pFET device region thereby exposing said Si film;
converting said Si film that is exposed in said at least one pFET device region into a SiGe film; and
forming at least one nFET device in said at least one nFET device region and at least one pFET device in said at least one pFET device region, said at least one nFET device including a Si gate and said at least one pFET including a SiGe gate.

2. The method of claim 1 wherein said Si film is amorphous or polycrystalline.

3. The method of claim 1 wherein said converting comprising introducing Ge atoms into said exposed Si film in said at least one pFET device region.

4. The method of claim 3 wherein said Ge atoms are generated by decomposing a Ge-containing source gas at a temperatures of about 200° C. or greater.

5. The method of claim 4 wherein said Ge-containing source gas comprises a GeₐX_{b} compound wherein a is 1 or 2, b is 2, 4 or 6, and each X is the same or different and is H (Hydrogen), Cl (Chlorine) or metallorganic compounds.

6. The method of claim 1 wherein said converting comprising forming a Ge-containing layer atop said exposed Si film in said pFET device region and diffusing Ge atoms from the Ge-containing layer into said exposed Si film.

7. The method of claim 6 wherein said diffusing comprising a heating step performed at a temperature of about 200° C. or greater in an inert ambient.

8. The method of claim 1 wherein said converting comprising forming a Ge-containing layer atop said exposed Si film in said pFET device region and performing a thermal oxidation process at a temperature from about 200° to about 1300° C.

9. The method of claim 1 further comprising forming an additional Si film atop said Si film and said SiGe film in both of said device regions.

10. A method of forming a semiconductor structure comprising:
providing a material stack comprising, from bottom to top, a gate dielectric, a Si film, and a hard mask on a surface of a semiconductor substrate, said substrate including at least one nFET device region and at least one pFET device region;
selectively removing said hard mask from said material stack in said at least one pFET device region thereby exposing said Si film;
introducing Ge atoms into said Si film that is exposed in said at least one pFET device region to form a SiGe film; and
forming at least one nFET device in said at least one nFET device region and at least one pFET device in said at least one pFET device region, said at least one nFET device including a Si gate and said at least one pFET including a SiGe gate.

11. The method of claim 10 wherein said Ge atoms are generated by decomposing a Ge-containing source gas at a temperatures of about 200° C. or greater.

12. The method of claim 10 wherein said Ge-containing source gas comprises a GeₐX_{b} compound wherein a is 1 or 2, b is 2, 4 or 6, and each X is the same or different and is H (Hydrogen), Cl (Chlorine) or metallorganic compounds

13. The method of claim 10 further comprising performing a thermal oxidation process or a diffusion anneal between said steps of introducing Ge atoms and forming said at least one nFET device and said at least one pFET device.

14. The method of claim 10 further comprising forming an additional Si film atop said Si film and said SiGe film in both of said device regions.

15. A method of forming a semiconductor structure comprising:
providing a material stack comprising, from bottom to top, a gate dielectric, a Si film, and a hard mask on a surface of a semiconductor substrate, said substrate including at least one nFET device region and at least one pFET device region;
selectively removing said hard mask from said material stack in said at least one pFET device region thereby exposing said Si film;
forming a Ge-containing film on said Si film that is exposed in said at least one pFET device region into a SiGe film;
annealing said Ge-containing film to introduce Ge atoms from said Ge-containing film into said Si film; and
forming at least one nFET device in said at least one nFET device region and at least one pFET device in said at least one pFET device region, said at least one nFET device including a Si gate and said at least one pFET including a SiGe gate.

16. The method of claim 15 wherein annealing step is a thermal oxidation process that is performed at a temperature from about 200° to about 1300° C.

17. The method of claim 15 further comprising forming an additional Si film atop said Si film and said SiGe film in both of said device regions.

18. The method of claim 15 wherein said annealing step is a diffusion anneal that is performed at a temperature of about 200° C. or greater in an inert ambient.

19. A semiconductor structure comprises:
a first gate stack located within an nFET device region of a semiconductor substrate, said first gate stack comprising, from bottom to top, a gate dielectric, a first Si layer, and a second Si layer; and
a second gate stack located within a pFET device region of said semiconductor substrate, said second gate stack comprising, from bottom to top, the gate dielectric, a SiGe layer, and the second Si layer.

20. The semiconductor structure of claim 19 wherein said first Si layer and said SiGe layer are both polycrystalline.
